(19) United States
(12) Patent Application Publication
(10) Pub. No.: US 2002/0163777 A1
(43) Pub. Date: Nov. 7, 2002

(54) Notebook computer with a cassette for holding a communications device

(76) Inventors: Kang-Yeh Yu, Taipei (TW); Chuan-Yuan Lee, Taipei (TW)

Correspondence Address: NAIPO (NORTH AMERICA INTERNATIONAL PATENT OFFICE), P.O. BOX 506, MERRIFIELD, VA, 22116, US

(21) Appl. No.: 09/848,363

(22) Filed: May 4, 2001

(51) Int. Cl. G06F 1/16; H05K 5/00

(52) U.S. Cl. 361/683; 361/686

(57) ABSTRACT

A notebook computer includes a casing with a slot, communications circuitry disposed within the casing, and a cassette for supporting a portable communications device and capable of sliding within the slot. The portable communications device utilizes the communications circuitry to communicate with the notebook computer, and can be disposed within the cassette for support.

### BACKGROUND OF THE INVENTION

1. Field of the Invention

The present invention relates to a notebook computer, and more particularly, to a notebook computer with a cassette capable of sliding within a slot of a casing of the notebook computer. The cassette has a universal serial bus (USB) port for electrically connecting the computer to a portable communications device.

2. Description of the Prior Art

There are several ways to extend the functionality of a notebook computer, especially as regards accessing the Internet. For example, many notebook computers include a built-in modem, or a wireless LAN card for accessing the Internet. But built-in modems require a telephone line, and thus affect the mobility of the notebook computer. Wireless LAN cards require one of the PCMCIA slots of the notebook computer, and thus consume a limited resource within the computer. Even the integration of a portable communications device, such as a cellular phone, with the notebook computer is somewhat inconvenient as the two devices frequently exchange information by way of an infrared communication system, which generally lacks sufficient bandwidth for heavy transmission loads. On the other hand, if a cable is used to connect the portable communications device with the computer, there is often no convenient place to set the communications device.

### SUMMARY OF THE INVENTION

It is therefore an objective of the present invention to provide a notebook with a cassette that is capable of sliding within a slot of a casing of a notebook computer. The cassette serves as a holder for a portable communications device, and provides a USB port to enable the portable communications device to exchange digital information with the notebook computer. Under this system, the portable communications device is capable of serving as a built-in modem or a wireless LAN card of the notebook computer. With the large bandwidth of the USB port, the notebook computer is able to access the Internet anywhere with a high bandwidth, with the need to occupy one of the PCMCIA slots of the notebook computer. Additionally, as the cassette is adapted to hold the portable communications device, a convenient holder for the communications device is offered provided for the user.

In accordance of the claimed invention, a notebook computer is disclosed that includes a casing with a slot, communications circuitry disposed within the casing, and a cassette adapted to support a portable communications device and capable of sliding within the slot. A portable communications device utilizes the communications circuitry to communicate with the notebook computer, and can be disposed within the cassette.

It is an advantage of the present invention that the portable communications device maybe conveniently disposed within the cassette and uses the cassette to interface with the notebook computer. When not in use, the cassette may be hidden within the notebook computer by sliding the cassette within the slot. Interfacing the notebook computer with the communications device is thus made easier for a user. With a USB port available from the cassette, connecting the communications device to the notebook computer is simple, and the USB port offers a high communications bandwidth. No PCMCIA slot need therefore be used, nor is the notebook computer then limited to the availability of a telephone jack.

These and other objectives of the present invention will no doubt become obvious to those of ordinary skill in the art after reading the following detailed description of the preferred embodiment, which is illustrated in the various figures and drawings.

### BRIEF DESCRIPTION OF THE DRAWINGS

FIG. 1 is a simplified block diagram of a present invention computer system.

FIG. 2 is a perspective view of the computer system of FIG. 1.

FIG. 3 is another embodiment of a notebook computer according to the present invention.

### DETAILED DESCRIPTION OF THE PREFERRED EMBODIMENT

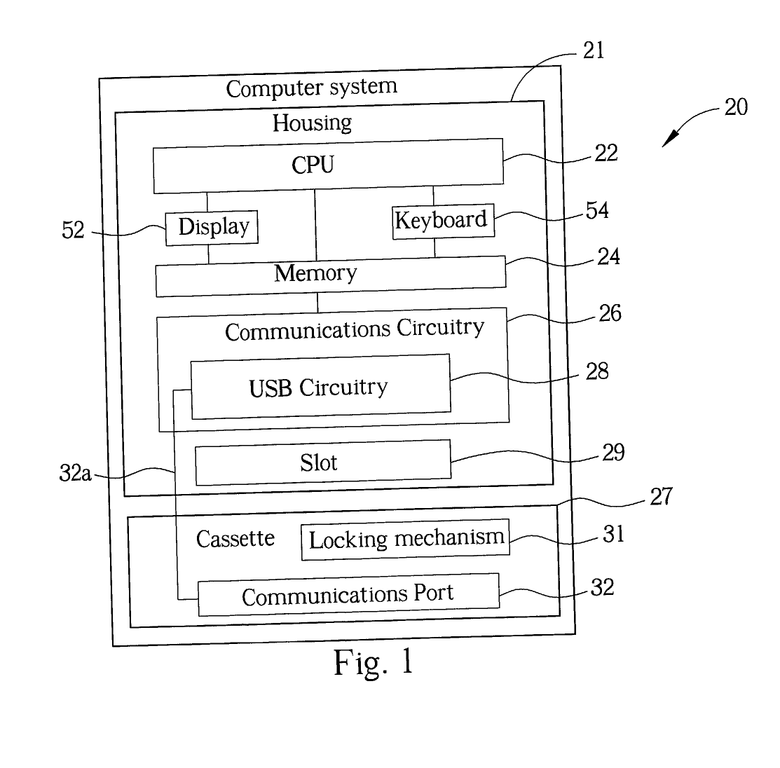

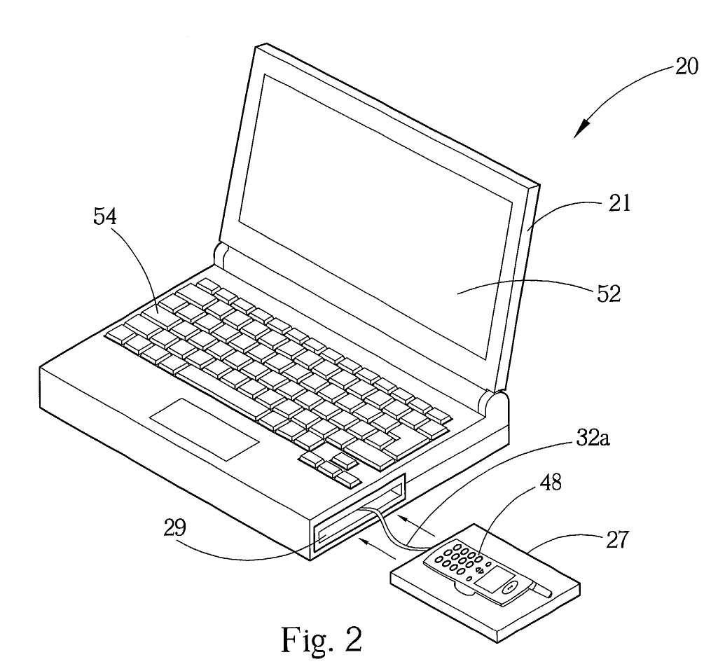

Please refer to FIG. 1 and FIG. 2. FIG. 1 is a simplified block diagram of a present invention computer system 20. FIG. 2 is a perspective view of the computer system 20. The computer system 20 includes a housing 21 with a slot 29. Disposed within the housing 21 is a CPU 22 for controlling operations of the computer system 20, a display 52, a keyboard 54, a memory for storing application programs and digital information for the computer system 20, and communications circuitry 26 that includes universal serial bus (USB) circuitry 28 connected electrically to a communications port 32 of the notebook computer. The communications port 32 is used to exchange information with peripherals connected to the computer system 20, and is a USB port 32. The computer system 20 also includes a cassette 27 that is adapted to receive a portable communications device 48. The cassette 27 is capable of sliding within the slot 29. In the preferred embodiment, the USB port 32 is disposed within the cassette 27 so that the USB port 32 may be easily accessible to the communications device. A flexible wire 32a may be used to electrically connect the USS port 32 with the USB circuitry 28 so that the cassette 27 may slide in and out of the slot 29 while ensuring that the USB port 32 remains electrically connected to the USB circuitry 28. Although the USB port 32 is shown disposed within the cassette 27, it should be clear to one in the art that this is not necessary. The USB port 32 could also be disposed on the housing 21 of the computer system 20. However, it is believed that by providing the USB port 32 on the cassette 27, the communications device 48 may be more easily integrated with the computer system 20. The portable communication device 48 may be, for example, a cellular phone or a personal data assistant (PDA).

The communications circuitry 26 includes at least one communication bus, which enables the exchange of digital information with devices outside of the computer system 20. The USB circuitry 28 can be regarded as one of the communication buses. With the USB standard becoming more and more popular, it is possible that the communication buses described here may all be USB buses. Generally speaking, though, this is not the case, and many other communication buses may be present, such as serial (RS-232) buses, parallel buses, SCSI buses, IEEE 1394, etc. Adopting the USB standard for the communications port 32 in this embodiment is simply for the purpose of explaining the present invention easily. Other communications standards could certainly be substituted.

The cassette 27 includes a locking mechanism 31 that mechanically interfaces with the housing 21, allowing the cassette 27 to slide out of the slot 29 for use, or to be locked within the slot 29 when not in use. The cassette 46 includes a communications port as the communications port 32 described in FIG. 1, which is electrically connected to the communications circuitry 26 also shown in FIG. 1. When the portable communications device 48 is connected to the communications port 32 of the cassette 27, the portable communications device 48 is able to utilize the communications port 32 of the cassette 27 to electrically connect to the communications circuitry 26. As indicated previously, in the preferred embodiment as shown in FIGS. 1 and 2, the communications port 32 is a USB port 32, and is electrically connected to the USB circuitry 28 by way of the flexible wire 32a. The portable communication device 48 may thus be used by the computer system 20 as a dialer. Thus, the notebook computer 20 directly accesses the Internet by way of the portable communications device 48. The portable communications device 48 is conveniently disposed within the cassette 27. If the portable communications device 48 is sufficiently thin, then both the cassette 27 and the portable communications device 48 may be disposed within the housing 21 of notebook computer 20.

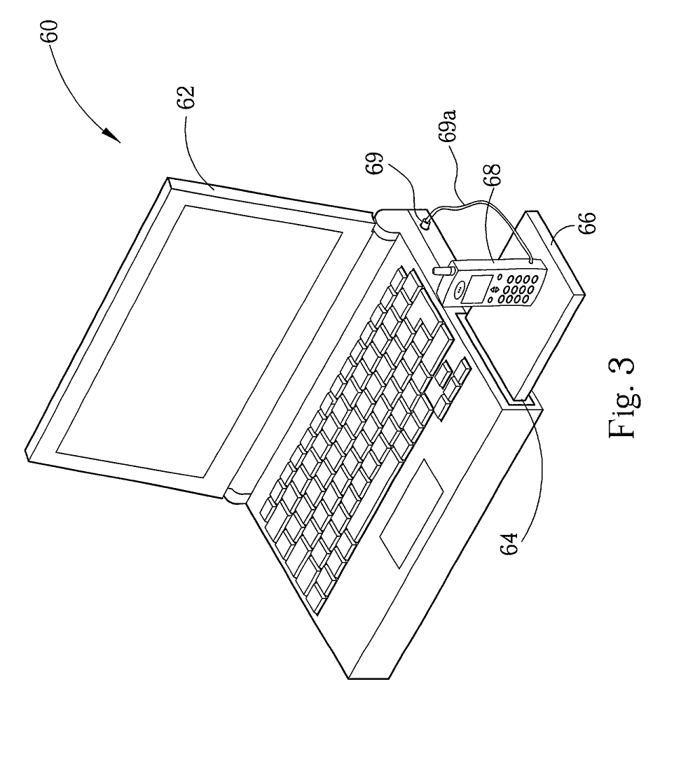

Please refer to FIG. 3. FIG. 3 is an alternate embodiment of a notebook 60 according to the present invention. The notebook 60 has a housing 62 with a slot 64, and a cassette 66 slidably disposed within the slot 64. The cassette 66 is adapted to receive a portable communications device 68, and acts as a stand or holder for the communications device 68. The cassette 66 is not, however, provided with a communications port. Instead, a communications port 69, such as a USB port, is located on the housing 62 of the notebook 60. A flexible cable 69a is used to electrically connect the communications device 68 with the communications port 69. When the communications device 68 is no longer needed, the communications device 68 is removed from the cassette 66, and the cassette 66 can be stowed away in the notebook 60 by sliding the cassette 66 into the slot 64.

In contrast with the prior art, the present invention provides a notebook computer with a cassette that is slidably disposed within a slot of the housing of the notebook computer. The cassette is adapted to support a portable communications device. The cassette includes a USB port that enables the portable communications device to connect with USB circuitry of the notebook computer. With this integration method for the notebook computer and the portable communications device, a convenient holding place is provided for the portable communications device.

Those skilled in the art will readily observe that numerous modifications and alterations of the device may be made while retaining the teachings of the invention. Accordingly, the above disclosure should be construed as limited only by the metes and bounds of the appended claims.

What is claimed is:

1. A notebook computer comprising:
a casing with a slot;
communications circuitry disposed within the casing; and
a cassette adapted to support a portable communications device and capable of sliding within the slot;
wherein a portable communications device utilizing the communications circuitry to communicate with the notebook computer can be disposed within the cassette.

2. The notebook computer of claim 1 wherein the portable communications device is a cellular phone.

3. The notebook computer of claim 1 wherein the portable communications device is a personal data assistant (PDA).

4. The notebook computer of claim 1 wherein when the portable communications device is positioned on the cassette, the cassette is slidably disposed within the slot.

5. The notebook computer of claim 1 wherein the cassette comprises a communications port electrically connected to the communications circuitry, the portable communications device utilizing the communications port to electrically connect to the communications circuitry.

6. The notebook computer of claim 5 wherein the communications port is a universal serial bus (USB) port.

7. The notebook computer of claim 1 wherein the communications circuitry comprises universal serial bus (USB) circuitry.
